(19) United States
(12) Patent Application Publication
(10) Pub. No.: US 2026/0255812 A1
(43) Pub. Date: Aug. 27, 2026

(54) LIGHT EMITTING DISPLAY APPARATUS

(71) Applicant: LG Display Co., Ltd., Seoul (KR)

(72) Inventors: Sangjin Kim, Paju-si (KR); Youngwan Ryu, Paju-si (KR)

(73) Assignee: LG Display Co., Ltd., Seoul (KR)

(21) Appl. No.: 19/425,533

(22) Filed: Dec. 18, 2025

(30) Foreign Application Priority Data
Feb. 27, 2025 (KR) 10-2025-0026225

(51) Int. Cl. H10K 59/124; H10K 59/121; H10K 59/131; H10K 59/80

(52) U.S. Cl. CPC H10K 59/124; H10K 59/1213; H10K 59/131; H10K 59/873

(57) ABSTRACT

A light emitting display apparatus may comprise a substrate including a display area and a non-display area; a pixel circuit layer including a gate line and a data line configured at the display area, and a pixel circuit connected to the gate line and the data line; a first overcoat layer configured to cover the pixel circuit layer; a second overcoat layer over the first overcoat layer; a light emitting device layer over the first overcoat layer and the second overcoat layer and configured to connect to the pixel circuit; a gate driving circuit configured at the non-display area and connected to the gate line; a third overcoat layer in a same layer as the first overcoat layer and configured to cover the gate driving circuit; a step compensation layer over the third overcoat layer; and a trench part between the first overcoat layer and the third overcoat layer.

### CROSS-REFERENCE TO RELATED APPLICATION

This application claims the benefit of and priority to Korean Patent Application No. 10-2025-0026225, filed on Feb. 27, 2025, the entirety of which is hereby incorporated by reference for all purposes as if fully set forth herein.

### BACKGROUND

### Technical Field

The present disclosure relates to a light emitting display apparatus.

### Description of the Related Art

A light emitting display apparatus is a self-luminous display device that does not require a separate light source, unlike liquid crystal display apparatus. Thus, the light emitting display apparatus may be manufactured in a lightweight and thin manner. In addition, the light emitting display apparatus is in the spotlight as a next-generation display apparatus because it is advantageous in terms of power consumption by driving low voltage and has excellent color arrangement, response speed, viewing angle, and contrast ratio.

The light emitting display apparatus displays an image through light emission of a light emitting device layer including a light emitting device interposed between two electrodes. In this case, light generated according to light emission of the light emitting device is emitted to the outside through a substrate or the like.

### SUMMARY

Recently, a light emitting display apparatus of a side mirror scheme has been developed in which two overcoat layers are configured on a thin film transistor, and an anode electrode is disposed at an upper surface of an overcoat layer configured at a lower portion of the two overcoat layers and a side surface of an overcoat layer configured at an upper portion of the two overcoat layers to improve a light extraction efficiency and viewing angle performance of the light emitting display apparatus.

In the light emitting display apparatus of the side mirror scheme, as the two overcoat layers are configured, a thickness of the overcoat layer may increase. Accordingly, a moisture may penetrate into an inside of a display panel through the overcoat layer in an outer area or a non-display area of the light emitting display apparatus. To prevent or suppress this, a portion of the overcoat layer disposed at the non-display area may be removed to block a moisture permeation path. However, if the portion of the overcoat layer is removed, in a subsequent bank forming process, a bank material may flow down (or overflow) due to a step difference of the overcoat layer. In this case, in the outer area or the non-display area of the light emitting display apparatus, a thickness of the bank may become smaller. Accordingly, a viewing angle and luminance of pixels disposed in an emission region adjacent to the non-display area of the light emitting display apparatus may be reduced.

To solve the above-described problems, the inventors of the present disclosure have conducted various experiments, and through the various experiments, invented a light emitting display apparatus having a new structure capable of preventing or suppressing penetration of hydrogen and moisture and improving a viewing angle and luminance.

One or more aspects of the present disclosure are directed to providing a light emitting display apparatus capable of preventing or suppressing penetration of hydrogen and moisture.

One or more aspects of the present disclosure are directed to providing a light emitting display apparatus capable of improving a viewing angle and luminance.

One or more aspects of the present disclosure are directed to providing a light emitting display apparatus with improved reliability.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a light emitting display apparatus according to an example embodiment of the present disclosure may comprise a substrate including a display area and a non-display area; a pixel circuit layer including a gate line and a data line configured at the display area, and a pixel circuit connected to the gate line and the data line; a first overcoat layer configured to cover the pixel circuit layer; a second overcoat layer over the first overcoat layer; a light emitting device layer over the first overcoat layer and the second overcoat layer and configured to connect to the pixel circuit; a gate driving circuit configured at the non-display area and connected to the gate line; a third overcoat layer in a same layer as the first overcoat layer and configured to cover the gate driving circuit; a step compensation layer over the third overcoat layer; and a trench part between the first overcoat layer and the third overcoat layer.

Details of this and other example embodiments will be included in the detailed description of the disclosure and the accompanying drawings.

According to an example embodiment of the present disclosure, the light emitting display apparatus comprises a trench part, and thus, penetration of hydrogen and moisture may be prevented or suppressed, and deterioration of the light emitting display apparatus may be prevented or suppressed.

According to an example embodiment of the present disclosure, the light emitting display apparatus comprises a step compensation layer configured at a non-display area of the substrate, whereby a reduction in a thickness of a bank in an outermost emission region may be prevented or suppressed, and thus, a viewing angle and luminance of the light emitting display apparatus may be improved.

According to one or more example embodiments of the present disclosure, the light emitting display apparatus with improved reliability may be provided, a long lifespan may be realized, and low-power driving may be possible.

Other systems, methods, features and advantages will be, or will become, apparent to one with skill in the art upon examination of the following figures and detailed description. It is intended that all such additional systems, methods, features and advantages be included within this description, and be within the scope of the present disclosure. Nothing in this section should be taken as a limitation on those claims. Further aspects and advantages are discussed below in conjunction with aspects of the disclosure.

It is to be understood that both the foregoing description and the following description of the present disclosure are by way of example and explanatory and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this disclosure, illustrate aspects and embodiments of the present disclosure and together with the description serve to explain principles of the disclosure. However, the technical features of embodiments of the present disclosure are not limited to those shown in the specific drawings, and the features disclosed in each drawing may be combined to form a new embodiment.

FIG. 1 is a plan view illustrating a light emitting display apparatus according to an example embodiment of the present disclosure.

FIG. 2 is an example diagram illustrating a structure of a gate driving circuit applied to a light emitting display apparatus according to an example embodiment of the present disclosure.

FIG. 3 is a cross-sectional view taken along line I-I′ in FIG. 1.

FIG. 4 is a cross-sectional view taken along line II-II′ in FIG. 1.

FIG. 5 is an enlarged view illustrating portion ‘A’ illustrated in FIG. 4.

FIG. 6 is a cross-sectional view taken along line III-III′ in FIG. 1.

FIG. 7 illustrates luminance according to a viewing angle of a light emitting display apparatus according to an example embodiment of the present disclosure.

FIG. 8A is a diagram illustrating a pixel of a light emitting display apparatus according to an experimental example.

FIG. 8B is a diagram illustrating a pixel of a light emitting display apparatus according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions, and elements, and depiction thereof may be exaggerated for clarity, illustration, and convenience.

### DETAILED DESCRIPTION

Advantages and features of the present disclosure, and implementation methods thereof, are clarified through the following example aspects described with reference to the accompanying drawings. The present disclosure may, however, be embodied in different forms and should not be construed as limited to the example aspects set forth herein. Rather, these example aspects are examples and are provided so that this disclosure may be more thorough and complete to assist those skilled in the art to understand the inventive concepts without limiting the protected scope of the present disclosure.

A shape, a size, a ratio, an angle, and a number disclosed in the drawings for describing example embodiments of the present disclosure are merely examples, and the present disclosure is thus not limited to the illustrated details. Like reference numerals refer to like elements throughout unless otherwise specified. In the following description, where the detailed description of the relevant known function or configuration may unnecessarily obscure aspects or features of the present disclosure, such detailed description may be omitted. In addition, where terms like “comprise,” “have,” and “include” are used in the present disclosure, another part may be added unless a more specific term like “only” is used. The terms of a singular form can include plural forms, and vice versa, unless referred to the contrary.

In construing an element, the element is to be construed as including an error range although there is no explicit description.

In describing a position relationship, for example, where a position relation between two parts is described as “on,” “over,” “under,” “next,” “adjacent to,” or the like, one or more other parts may be located between the two parts unless a more limiting term, such as “immediate(ly),” “direct(ly),” or “close(ly),” is used.

In describing a time relationship, for example, where the temporal order is described as, for example, “after,” “subsequent,” “next,” “before,” or the like, a case that is not continuous may be included unless a more limiting term, such as “just,” “immediate(ly),” or “direct(ly),” is used.

It should be understood that, although terms like “first,” “second,” etc., may be used herein to describe various elements, these elements should not be limited by these terms. These terms are only used to refer to one element separately from another. For example, a first element could be termed a second element, and similarly, a second element could be termed a first element, without departing from the scope of the present disclosure.

In describing elements of the present disclosure, such terms as “first,” “second,” “A,” “B,” “(a),” “(b),” etc., may be used. These terms are intended to identify the corresponding elements separately from the other elements, and basis, order, or number of the corresponding elements should not be limited by these terms. The expression that an element or layer is “connected,” “coupled,” or “adhered” to another element or layer means that the element or layer may encompass not only being directly connected or adhered to another element or layer, but also being indirectly connected or adhered to another element or layer with one or more intervening elements or layers “disposed” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item, as well as the first item, the second item, or the third item individually.

Features of various aspects of the present disclosure may be partially or wholly coupled to or combined with each other, and may be variously inter-operated with each other and driven technically as those skilled in the art may sufficiently understand. Aspects of the present disclosure may be carried out independently from each other or may be carried out together in co-dependent relationship.

Hereinafter, example embodiments of the present disclosure will be described in detail with reference to the accompanying drawings. For convenience of description, a scale of each element illustrated in the accompanying drawings may differ from a real scale. Thus, the illustrated element is not limited to a scale illustrated in the drawings.

The light emitting display apparatus according to an example embodiment of the present disclosure may be a flexible light emitting display apparatus, a light emitting display panel, or a flexible light emitting display panel, but embodiments of the present disclosure are not limited thereto. For example, the light emitting display apparatus according to an example embodiment of the present disclosure may include a set electronic apparatus or a set device (or a set apparatus) such as a notebook computer, a television, a computer monitor, an equipment apparatus including a light emitting display apparatus for vehicles (or an automotive) or another type apparatus for vehicles, or a mobile electronic apparatus such as a smartphone or an electronic pad and or the like, which is a complete product (or a final product) including a light emitting display panel.

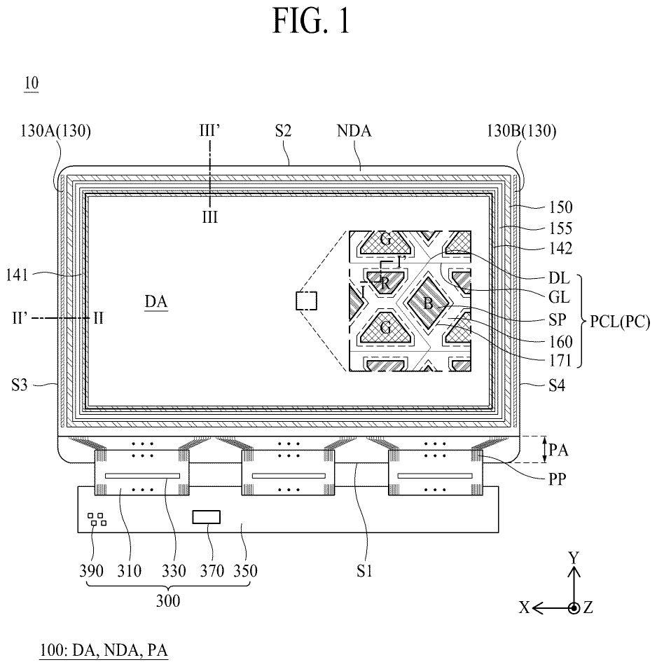

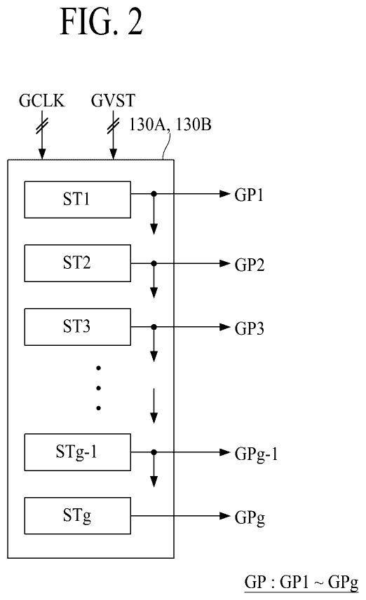

FIG. 1 is a plan view illustrating a light emitting display apparatus according to an example embodiment of the present disclosure. FIG. 2 is an example diagram illustrating a structure of a gate driving circuit applied to a light emitting display apparatus according to an example embodiment of the present disclosure.

As shown in FIGS. 1 and 2, a light emitting display apparatus (or light emitting display panel) 10 according to an example embodiment of the present disclosure may include a substrate 100 having a display area DA, a non-display area NDA, and a pad area PA.

The display area DA may be an area which displays an image, and may be a pixel array area, an active area, a pixel array part, a display part, or a screen. For example, the display area DA may be disposed at a central portion of the light emitting display apparatus (or the light emitting display panel).

The non-display area NDA may be an area which does not display an image. The non-display area NDA may be a peripheral region of the display area DA. For example, the non-display area NDA may be implemented to surround the display area DA. For example, the non-display area NDA may include an edge portion of the substrate 100. For example, the non-display area NDA may be a non-display part, an inactive area, an inactive part, a peripheral part, or a peripheral area.

The pad area PA may be an extension region extending from one side of the non-display area NDA. The pad area PA may be an area extending from at least a portion of a long-side (or a first long-side) of one side of the non-display area NDA to have a predetermined length along a second direction Y. The pad area PA may include a plurality of data link lines. Each of the plurality of data link lines may electrically connect a plurality of display data pads to a plurality of data lines in a one-to-one correspondence. The pad area PA may include a plurality of gate link lines. Each of the plurality of gate link lines may connect a plurality of display gate pads and the gate driving circuit 130.

According to an example embodiment of the present disclosure, the substrate 100 may include a first long-side S1, a second long-side S2, a first short-side S3, and a second short-side S4. The first long-side S1 and the second long-side S2 face each other and may be disposed parallel to each other in the second direction Y. The first short-side S3 and the second short-side S4 face each other and may be disposed parallel to each other in the first direction X.

The light emitting display apparatus (or the light emitting display panel) 10 according to an example embodiment of the present disclosure may include a pixel circuit layer PCL, a gate driving circuit 130, a step compensation layer 150, a trench part 155, and a plurality of pad parts PP.

The pixel circuit layer PCL may be disposed (or implemented) at the display area DA of the substrate 100 and may display a black and white image or a color image. For example, the pixel circuit layer PCL may be a pixel layer, a pixel array, a pixel array layer, or a pixel array part.

The pixel circuit layer PCL may include a plurality of sub-pixels SP. For example, the plurality of sub-pixels SP may be disposed to have a planar structure of a pentile type. For example, a first electrode 171 of each of the plurality of sub-pixels SP may be disposed to have the planar structure of the pentile type. For example, the first electrode 171 may be an anode electrode or a pixel electrode.

An edge portion of the first electrode 171 of each of the plurality of sub-pixels SP may be covered by a bank 160. The bank 160 may define an opening portion of each of the plurality of sub-pixels SP by including an opening portion corresponding to (or overlapping) a central portion of the first electrode 171.

In FIG. 1, the first electrode 171 of each of the plurality of sub-pixels SP is illustrated as having the planar structure of the pentile type, but it is not limited thereto. For example, the first electrode 171 of each of the plurality of sub-pixels SP may have a planar structure of an RGB stripe type or a planar structure of RGBW stripe type.

Each of the plurality of sub-pixels SP may be configured in each pixel areas provided by pixel drive lines. The pixel drive lines may include a plurality of gate lines GL and a plurality of data lines DL configured at the display area DA. Each of the plurality of pixels UP may be implemented at each pixel areas provided by the plurality of gate lines GL and the plurality of data lines DL.

The pixel circuit layer PCL may include a light emitting device layer having an emission structure. For example, the emission structure may include a light emitting layer (or an organic light emitting layer), but is not limited thereto, and the emission structure may include an inorganic light emitting layer (or an inorganic light emitting diode).

Each of the plurality of sub-pixels SP may be configured to implement any one of a plurality of colors (or light) implementing a color image (or color light). For example, each of the plurality of sub-pixels SP may be configured to include a light emitting device implementing any one of red light, green light, and blue light.

The light emitting display apparatus 10 according to an example embodiment of the present disclosure may include a first overcoat layer 141. The first overcoat layer 141 may be disposed at a display area DA of the substrate 100 so as to cover the pixel circuit PC. The first overcoat layer 141 may be configured in a portion of the non-display area NDA adjacent to the display area DA from the display area DA of the substrate 100 so as to cover the pixel circuit PC. The first overcoat layer 141 may be configured to planarize an upper portion of the pixel circuit PC and to protect the pixel circuit PC.

The light emitting display apparatus 10 according to an example embodiment of the present disclosure may include a second overcoat layer 142. The second overcoat layer 142 may be disposed over the first overcoat layer 141. The second overcoat layer 142 may be configured in the portion of the non-display area NDA adjacent to the display area DA from the display area DA of the substrate 100. The second overcoat layer 142 may be configured to implement a side mirror structure of the emission structure.

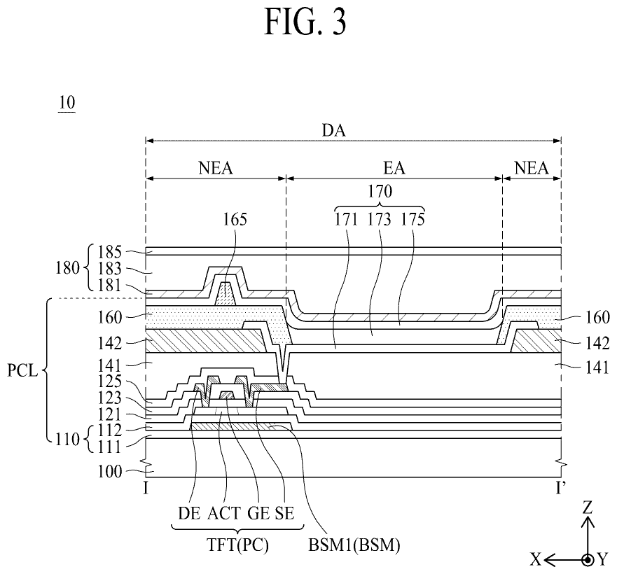

According to an example embodiment of the present disclosure, the first electrode 171 may be disposed at an upper surface of the first overcoat layer 141 and a side surface (or a lateral surface) of the second overcoat layer 142 adjacent to the upper surface of the first overcoat layer 141, thereby implementing a side mirror structure that induces side reflection of the emission structure (or a light emitting device or light emitting layer). The specific configurations of the first overcoat layer 141, the second overcoat layer 142, and the emission structure will be described below with reference to FIG. 3.

The gate driving circuit 130 may be configured at the non-display area NDA. The gate driving circuit 130 may be implemented at the non-display area NDA adjacent to the display area DA to be electrically connected to the plurality of gate lines GL. The gate driving circuit 130 may be implemented in an area (or a first short-side area) of the first short-side S3 and/or an area (or a second short-side area) of the second short-side S4 of the non-display area NDA to be electrically connected to the plurality of gate lines GL. For example, the gate driving circuit 130 may be implemented in one or more of a pair of short-side areas S3 and S4 of the non-display area NDA to be electrically connected to the plurality of gate lines GL.

According to an example embodiment of the present disclosure, the gate driving circuit 130 may be directly formed or implemented on the substrate 100 by a manufacturing process of thin film transistors of the sub-pixels SP based on a GIP (gate in panel) scheme. For example, the gate driving circuit 130 may be a gate built-in circuit (or an embedded gate circuit) or a gate shift register circuit, but embodiments of the present disclosure are not limited thereto.

The gate driving circuit 130 may supply gate pulses GP1 to GPg to the gate lines GL. When a gate pulse (or a gate on signal) GP generated by the gate driving circuit 130 is supplied to the gate of a transistor which is provided in a subpixel SP, the transistor may be turned on. When a gate off signal generated by the gate driving circuit 130 is supplied to the transistor, the transistor may be turned off.

A gate signal supplied to the gate line GL may include the gate pulse GP and the gate off signal. To supply the gate pulses GP1 to GPg to the gate lines GL, the gate driving circuit 130 may include stages ST1 to STg connected to each of the gate lines GL, as illustrated in FIG. 2.

To generate the gate pulses GP1 to GPg, at least one or more gate start signals GVST generated by a control signal generating part and at least two gate clocks GCLK generated by a shift driver may be transmitted to the gate driving circuit 130. That is, the at least one or more gate start signals GVST and the at least two gate clocks GCLK may be included in gate control signals.

Any one of the stages ST1 to STg may be driven by the gate start signal GVST to output the gate pulse GP to the gate line GL. The gate pulse GP may be generated by the gate clock GCLK. Each of the remaining stages of the stages ST1 to STg may start operation using a carry signal supplied from a preceding stage, and sequentially generate gate pulses GP to output to the gate lines GL.

According to an example embodiment of the present disclosure, the gate driving circuit 130 may be configured at the non-display area NDA adjacent to the first short-side S3 of the substrate 100, or may be configured at the non-display area NDA adjacent to the second short-side S4 of the substrate 100.

The gate driving circuit 130 according to an example embodiment of the present disclosure may include one or more of a first gate driving circuit 130A and a second gate driving circuit 130B.

The first gate driving circuit 130A may be disposed at the non-display area NDA adjacent to the first short-side S3 of the substrate 100. The first gate driving circuit 130A may be configured at a first short-side area of the non-display area NDA adjacent to a first side (or one side) of the display area DA.

The second gate driving circuit 130B may be disposed at the non-display area NDA adjacent to the second short-side S4 of the substrate 100. The second gate driving circuit 130B may be configured at a second short-side area of the non-display area NDA adjacent to a second side (or the other side), which is opposite to the first side, of the display area DA.

According to an example embodiment of the present disclosure, the first gate driving circuit 130A may be electrically connected to one end of each of the plurality of gate lines GL disposed in the pixel circuit layer PCL, and the second gate driving circuit 130B may be electrically connected to the other end of each of the plurality of gate lines GL disposed in the pixel area.

According to another example embodiment of the present disclosure, the first gate driving circuit 130A may be electrically connected to the one end of each odd-numbered (or even-numbered) gate line among the plurality of gate lines GL disposed in the pixel circuit layer PCL, and the second gate driving circuit 130B may be electrically connected to the other end of each even-numbered (or odd-numbered) gate line among the plurality of gate lines GL disposed in the pixel circuit layer PCL.

The light emitting display apparatus 10 according to an example embodiment of the present disclosure may include a step compensation layer 150 and a trench part 155.

The step compensation layer 150 may be configured at the non-display area NDA of the substrate 100. The step compensation layer 150 may be disposed around the second overcoat layer 142. The step compensation layer 150 may be spaced apart from the second overcoat layer 142.

The step compensation layer 150 may be disposed between the display area DA and the gate driving circuit 130. Accordingly, the step compensation layer 150 may be non-overlapped the gate driving circuit 130, but is not limited thereto. As another example, the step compensation layer 150 may be configured over the gate driving circuit 130 and may be partially overlapped a portion of the gate driving circuit 130.

The trench part 155 may be configured between the second overcoat layer 142 and the step compensation layer 150. The trench part 155 may be a portion where the first overcoat layer 141 is removed. The trench part 155 may be a recessed portion (or a concave portion) configured between the second overcoat layer 142 and the step compensation layer 150.

The step compensation layer 150 may be configured to prevent or suppress a bank material which is used as the bank 160 from flowing down (or overflowing) to an outer area of the substrate 100 due to a step difference of the first overcoat layer 141 and the second overcoat layer 142, in a subsequent bank forming process.

For example, when the first overcoat layer 141 is disposed at an entire surface of the display area DA and the non-display area NDA of the light emitting display apparatus 10, a moisture may penetrate into an inside of the display panel through the first overcoat layer 141 in the outer area or the non-display area NDA of the light emitting display apparatus 10. To prevent or suppress this, a portion of the first overcoat layer 141 disposed at the non-display area NDA may be removed to form the trench part 155. For example, the trench part 155 may be the portion of the first overcoat layer 141 which is removed at the non-display area NDA.

According to an example embodiment of the present disclosure, the light emitting display apparatus 10 include the trench part 155, and thus, a moisture permeation path from the outside may be blocked.

For example, as the overcoat layers 141 and 142 having a two-layered structure are configured at the light emitting display apparatus 10, an overall thickness of the overcoat layers 141 and 142 may be increased. Accordingly, when the trench part 155 is configured (or formed), in a subsequent bank forming process, a bank material may flow down (or overflow) to the trench part 155 and the outer area due to the step difference between the first and second overcoat layers 141 and 142 and the trench part 155. In this case, a thickness of the bank 160 disposed at side surfaces (or lateral surfaces) of the second overcoat layer 142 may be reduced. Accordingly, in pixels which is disposed at an emission region adjacent to the non-display area NDA of the light emitting display apparatus 10, light emission defects may be occurred, and a viewing angle and luminance may be reduced.

According to an example embodiment of the present disclosure, the light emitting display apparatus 10 include the step compensation layer 150, and thus, in the bank forming process, a bank material may be prevented or suppressed from flowing down (or overflowing) toward the trench part 155 and an outer region direction due to the step difference of the first and second overcoat layers 141 and 142.

Accordingly, the light emitting display apparatus 10 according to an example embodiment of the present disclosure may include the trench part 155 and the step compensation layer 150, and thus, penetration of hydrogen and moisture may be prevented or suppressed, and the viewing angle and the luminance of the light emitting display apparatus 10 may be improved.

The plurality of pad parts PP may be implemented in the pad area PA of the substrate 100. The plurality of pad parts PP may be disposed at a first edge portion adjacent to the first long-side S1 of the substrate 100. The plurality of pad parts PP may include data pads (or display data pads) connected to the data lines DL and gate pads (or display gate pads) connected to the gate driving circuit 130. The plurality of pad parts PP may be electrically connected to the pixel circuit. The plurality of pad parts PP may be electrically connected to the gate driving circuit 130. For example, the plurality of pad parts PP may be electrically connected to the pixel driving lines for driving the pixel circuit and electrically connected to the gate driving circuit 130.

Each of the plurality of pad parts PP may be disposed to have a predetermined interval along the first direction X. Each of the plurality of pad parts PP may include a plurality of pads. For example, each of the plurality of pad parts PP may include a plurality of display data pads, a plurality of pixel driving voltage pads, a plurality of cathode voltage pads, and a plurality of touch data pads. For example, a first pad part connected to the first data line among the plurality of pad parts PP may further include a plurality of gate pads. In addition, a last pad part connected to the last data line among the plurality of pad parts PP may further include a plurality of gate pads.

Each of the plurality of gate pads may be electrically connected to the gate driving circuit 130 through a plurality of gate control signal lines (or a plurality of gate link lines) disposed in the pad area PA. For example, the plurality of gate pads disposed in the first pad part may be electrically connected to the first gate driving circuit 130A through the plurality of gate control signal lines disposed in the pad area PA, and the plurality of gate pads disposed in the last pad part may be electrically connected to the second gate driving circuit 130B through the plurality of gate control signal lines disposed in the pad area PA.

The light emitting display apparatus (or the light emitting display panel) according to an example embodiment of the present disclosure may further include a panel driving circuit part 300.

The panel driving circuit part 300 (or an external panel circuit) may be connected to the pad parts PP of the light emitting display panel 10. The panel driving circuit part 300 may drive (or emits light) the plurality of sub-pixels SP disposed in the display area DA based on image data supplied from a host driving system, thereby displaying an image corresponding to the image data on the display area DA.

The panel driving circuit part 300 according to an example embodiment may include a plurality of flexible circuit films 310, a plurality of data driving integrated circuits 330, a printed circuit board 350, a timing control part 370, and a power circuit part 390.

One side edge portion (or an input bonding portion) of each of the plurality of flexible circuit films 310 may be attached to or electrically connected to the printed circuit board 350 through a film attachment process using an anisotropic conductive film. The other side edge portion (or an output bonding portion) of each of the plurality of flexible circuit films 310 may be attached to or electrically connected to the plurality of pad parts PP of the substrate 100 through a film attachment process using an anisotropic conductive film. Each of the plurality of flexible circuit films 310 may be bent or folded toward a rear surface of the substrate 100 to surround a side surface (or a lateral surface) of the substrate 100. For example, the one side edge portion of each of the plurality of flexible circuit films 310 may be disposed on the rear surface of the substrate 100.

Each of the plurality of data driving integrated circuits 330 may be individually mounted on each of the plurality of flexible circuit films 310. Each of these data driving integrated circuits 330 may receive pixel data and data control signals provided from the timing control part 370, and convert the pixel data into analog pixel data signals for each pixel based on the data control signal to supply to corresponding data lines. For example, the flexible circuit films 310 and the data driving integrated circuits 330 may be referred to as data driving circuits or the like, but are not limited thereto.

The printed circuit board 350 may support the timing control part 370 and the power circuit part 390 and may transfer signals and powers between the components of the panel driving circuit part 300. For example, the printed circuit board 350 may be attached to the rear surface of the substrate 100 using an adhesive member.

The timing control part 370 may be mounted on the printed circuit board 350 and may receive image data and timing synchronization signals which are provided from a host driving system through a user connector disposed on the printed circuit board 350. The timing control part 370 may generate the pixel data by aligning the image data so as to match a pixel arrangement structure in the display area DA based on the timing synchronization signals and provide the generated pixel data to the corresponding data driving integrated circuits 330. In addition, the timing control part 370 may generate data control signals and gate control signals based on the timing synchronization signals, control the driving timing of each of the plurality of data driving integrated circuits 330 through the data control signals, and control the driving timing of the first and second gate driving circuits 130A and 130B through the gate control signals.

The power circuit part 390 may be mounted on the printed circuit board 350 and may generate various voltages for displaying an image on the light emitting display apparatus (or the light emitting display panel) 10 using an input power supplied from the outside and provide the generated voltages to the corresponding circuits.

FIG. 3 is a cross-sectional view taken along line I-I′ of FIG. 2. FIG. 3 schematically illustrates one sub-pixel illustrated in FIG. 1.

As shown in FIGS. 1 and 3, the light emitting display apparatus (or the light emitting display panel) 10 according to an example embodiment of the present disclosure may include a substrate 100, a pixel circuit layer PCL and an encapsulation part 180.

The substrate 100 includes thin film transistors, and may be a transistor array substrate, a lower substrate, a base substrate, or a first substrate. The substrate 100 may include a display area DA. The display area DA may include an emission area EA and a non-emission area NEA around the emission area EA. For example, the substrate 100 may be a transparent glass substrate or a transparent plastic substrate.

The pixel circuit layer PCL may include a buffer layer 110, a light blocking layer BSM, a pixel circuit PC, a first overcoat layer 141, a second overcoat layer 142, and a light emitting device layer 170.

The buffer layer 110 may be disposed on the substrate 100. The buffer layer 111 may prevent or suppress a material of the substrate 100 from being diffused to a transistor in performing a high temperature process in a manufacturing process of the thin film transistors, or may prevent or suppress external water or moisture from penetrating into the light emitting device layer 170.

The buffer layer 110 may include a first buffer layer 111 and a second buffer layer 112.

The first buffer layer 111 may be disposed on the substrate 100. The first buffer layer 111 may be disposed over an entire upper surface of the substrate 100. The first buffer layer 111 may be disposed between the substrate 100 and the pixel circuit PC.

The second buffer layer 112 may be disposed on the first buffer layer 111. The second buffer layer 112 may be disposed to cover the light blocking layer BSM. The second buffer layer 112 may be configured between the light blocking layer BSM and an active layer ACT. The second buffer layer 112 may be configured between a first light blocking layer BSM1 and the active layer ACT of the pixel circuit PC.

The light blocking layer BSM may be configured between the first buffer layer 111 and the second buffer layer 112. The light blocking layer BSM may include a first light blocking layer BSM1. The first light blocking layer BSM1 may be disposed at the display area DA. The first light blocking layer BSM1 may be disposed under the pixel circuit PC. The first light blocking layer BSM1 may be configured to prevent or suppress changes in the threshold voltage Vth of thin film transistors in the pixel circuit PC caused by external light incident from outside the display panel.

The pixel circuit layer PCL may be disposed at the display area DA on the substrate 100. The pixel circuit layer PCL may include the pixel driving lines including the gate lines GL and the data lines DL which are configured at the display area DA. The pixel circuit layer PCL may include the pixel circuit PC connected to the gate lines GL and the data lines DL. The pixel circuit layer PCL may be disposed on the second buffer layer 112. The pixel circuit PC may include a driving thin film transistor TFT which is disposed at a pixel area (or a sub-pixel area) on the substrate 100 or on the second buffer layer 112.

The driving thin film transistor TFT may include an active layer ACT, a gate electrode GE, a source electrode SE, and a drain electrode DE.

The active layer ACT may be disposed on the substrate 100 or the second buffer layer 112. For example, the active layer ACT may include a semiconductor material based on metal oxide such as indium-gallium-zinc-oxide (IGZO), but is not limited thereto, and may include a semiconductor material based on silicon such as amorphous silicon or polycrystalline silicon. For example, the active layer ACT may be formed in a patterned shape by depositing a semiconductor material on the second buffer layer 112, performing a heat treatment process (or an annealing process) for stabilization, and performing a patterning process of the semiconductor material.

The active layer ACT may include a source region, a drain region, and a channel region between the source region and the drain region. The active layer ACT may be covered by a first insulating layer (or a gate insulating layer) 121.

The first insulating layer 121 may be configured in an island shape on only the channel region of the active layer ACT, or may be configured to cover an entire front surface of the buffer layer 110 or the substrate 100 including the active layer ACT. The first insulating layer 121 may be configured as an inorganic material, but is not limited thereto, and may be configured as an organic material.

The gate electrode GE may be disposed on the first insulating layer 121 to overlap the channel region of the active layer ACT. The gate electrode GE may be formed of a gate metal material. The gate electrode GE may be formed using a same process as the gate line GL described above with reference to FIG. 1.

The gate electrode GE may be covered by a second insulating layer (or an interlayer insulating layer) 123. The second insulating layer 123 may be formed on the first insulating layer 121 to cover the gate electrode GE. The second insulating layer 123 may be configured as an inorganic material, but is not limited thereto, and may be configured as an organic material.

The source electrode SE may be disposed on the second insulating layer 113 to be electrically connected to the source region of the active layer ACT. The source electrode SE may be electrically connected to the source region of the active layer ACT through a contact hole formed in the first insulating layer 121 and the second insulating layer 123 overlapping the source region of the active layer ACT.

The drain electrode DE may be disposed on the second insulating layer 123 to be electrically connected to the drain region of the active layer ACT. The drain electrode DE may be electrically connected to the drain region of the active layer ACT through a contact hole formed in the first insulating layer 121 and the second insulating layer 123 overlapping the drain region of the active layer ACT.

The source electrode SE and the drain electrode DE may be formed of a source/drain metal material. For example, the source electrode SE and the drain electrode DE may be configured as a same or different conductive materials as the gate electrode GE. The source electrode SE and the drain electrode DE may be formed together with the data line DL described above with reference to FIG. 1.

The pixel circuit PC may further include at least one switching thin film transistor and at least one capacitor, which are disposed at the pixel area. The at least one switching thin film transistor and the at least one capacitor may be formed together with the driving thin film transistor TFT.

A passivation layer 125 may be disposed at the display area DA. The passivation layer 125 may be disposed on the pixel circuit layer PCL. The pixel circuit PC may be covered by the passivation layer 125. The passivation layer 125 may be configured as an inorganic material, but is not limited thereto, and may also be configured as an organic material. As another example, the passivation layer 125 may be omitted.

The first overcoat layer 141 may be disposed at the display area DA. The first overcoat layer 141 may be disposed in the emission area EA and the non-emission area NEA. The first overcoat layer 141 may be disposed over the passivation layer 125. The first overcoat layer 141 may be disposed over the pixel circuit PC. The pixel circuit PC may be covered by the first overcoat layer 141. For example, the first overcoat layer 141 may be configured to planarize an upper portion of the pixel circuit PC and to protect the pixel circuit PC. The overcoat layer 141 may be configured as an organic material. For example, the overcoat layer 141 may be formed of an organic material including acrylic resin, epoxy resin, phenolic resin, polyamide resin, or polyimide resin.

The second overcoat layer 142 may be disposed at the display area DA. The second overcoat layer 142 may be disposed at the non-emission area NEA. The second overcoat layer 142 may not be configured in the emission area EA. The second overcoat layer 142 may be disposed over the first overcoat layer 141. For example, the second overcoat layer 142 may be configured to include an inclined surface (or a structure) where an upper surface is flat and a side surface is inclined. Accordingly, the first electrode 171, which is disposed subsequently, may be formed (or configured) along a portion of the upper surface and the side surface of the second overcoat layer 142. The second overcoat layer 142 may be configured as an organic material. The second overcoat layer 142 may be configured as a same material as the first overcoat layer 141, but is not limited thereto.

The light emitting device layer 170 may be disposed on the first overcoat layer 141 and the second overcoat layer 142. The light emitting device layer 170 may be electrically connected to the driving thin film transistor TFT or the pixel circuit PC on the first overcoat layer 141 and the second overcoat layer 142.

The light emitting device layer 170 may include a first electrode 171, a light emitting device 173, and a second electrode 175.

The first electrode 171 may be disposed in a patterned shape on the first overcoat layer 141 and the second overcoat layer 142. The first electrode 171 may be disposed at an upper surface of the first overcoat layer 141 exposed by the second overcoat layer 142. The upper surface of the first overcoat layer 141 exposed by the second overcoat layer 142 may be the emission area EA of the substrate 100. The first electrode 171 may be configured at the side surface and a portion of the upper surface of the second overcoat layer 142 adjacent to the upper surface of the first overcoat layer 141. The first electrode 171 may be configured at the side surface or the inclined surface of the second overcoat layer 142. Accordingly, light emitted from the light emitting device 173 may be reflected by the first electrode 171 which is configured at the side surface or the inclined surface of the second overcoat layer 142 and extracted in an external or an upper direction. Therefore, a light extraction efficiency of the light emitting display apparatus 10 may be improved.

The first electrode 171 may be electrically connected to a source electrode SE of the driving thin film transistor TFT through an electrode contact hole formed in the first overcoat layer 141. The first electrode 171 may be an anode electrode. For example, the light emitting display apparatus 10 according to an example embodiment of the present disclosure may have a top emission structure. The first electrode 171 may be a reflective electrode that reflects light.

The light emitting device 173 may be disposed on the first electrode 171. The light emitting device 173 may include one or more emission structures which is stacked on the first electrode 171 in the order or reverse order of a hole layer, a light emitting layer, and an electron layer. For example, the light emitting device 173 may be implemented to generate color light corresponding to a corresponding sub-pixel. For example, when the unit pixel includes red, green, and blue sub-pixels, the light emitting device 173 of the red sub-pixel may generate red light, the light emitting device 173 of the green sub-pixel may generate green light, and the light emitting device 173 of the blue sub-pixel may generate blue light.

The second electrode 175 may be disposed on the light emitting device 173. The second electrode 175 may be disposed on the light emitting device 173 so as to face the first electrode 171 with the light emitting device 173 therebetween. The second electrode 175 may be a cathode electrode. For example, the light emitting display apparatus 10 according to an example embodiment of the present disclosure may have the top emission structure. For example, the second electrode 175 may be a transparent electrode that transmits light.

The light emitting display apparatus 10 according to an example embodiment of the present disclosure may include a bank 160.

The bank 160 may be disposed to define an opening portion (or an emission region) of the sub-pixel SP and to cover an edge portion of the first electrode 171. For example, the bank 160 may be disposed on a second overcoat layer 142 to cover only the edge portion of the first electrode 171 except for a central portion of the first electrode 171. The bank 160 may configured to cover the second overcoat layer 142. For example, the bank 160 may be formed of an organic material or an inorganic material. For example, the bank 160 may include any one of a transparent bank, a semi-transparent bank, and a black bank. When the bank 160 is a black bank, the bank 160 may be formed of an organic material or an inorganic material including a black pigment.

The light emitting display apparatus 10 according to an example embodiment of the present disclosure may further include a spacer 165.

The spacer 165 may be disposed at a non-emission region NEA. The spacer 165 may be disposed over the bank 160. The spacer 165 may be disposed at a portion of an upper portion of the bank 160. In the non-emission region NEA, the second electrode 175 may be disposed over the spacer 165. In the non-emission region NEA, the second electrode 175 may be configured to cover the spacer 165. The spacer 165 may be configured to prevent or suppress direct contact between a screen mask and the substrate 100 (or the bank 160) during the deposition process of the light emitting device 173.

The light emitting device 173 may be disposed only at the opening portion of each sub-pixel SP provided by the bank 160, or may be disposed at the opening portion of each sub-pixel SP and on the side surface of the bank 160.

The encapsulation part (or an encapsulation layer) 180 may be configured to cover or surround the pixel circuit layer PCL. For example, the encapsulation part 180 may be disposed on the light emitting device layer 170 and may cover or surround the light emitting device layer 170. The encapsulation part 180 may be configured to protect the pixel circuit layer PCL. For example, the encapsulation part 180 may be configured to prevent or block oxygen or moisture from the outside from penetrating into the emission structure of the pixel circuit layer PCL.

The encapsulation part 180 may include one or more encapsulation parts. For example, the encapsulation part 180 may include one or more inorganic material layers and one or more organic material layers on the light emitting device layer 170. For example, the encapsulation part 180 may include a first encapsulation part 181, a second encapsulation part 183, and a third encapsulation part 185.

The first encapsulation part 181 may be disposed at the display area DA to cover the light emitting device layer 170. The first encapsulation part 181 may be disposed to cover the second electrode 175. For example, the first encapsulation part 181 may be an inorganic material layer.

The second encapsulation part 183 may be disposed on the first encapsulation part 181. The second encapsulation part 183 may be disposed at the display area DA. For example, the second encapsulation part 183 may be an organic material layer.

The third encapsulation part 185 may be disposed on the first encapsulation part 181 and the second encapsulation part 183. The third encapsulation part 185 may be disposed on the first encapsulation part 181 and the second encapsulation part 183 configured at the display area DA. For example, the third encapsulation part 185 may be an inorganic material layer.

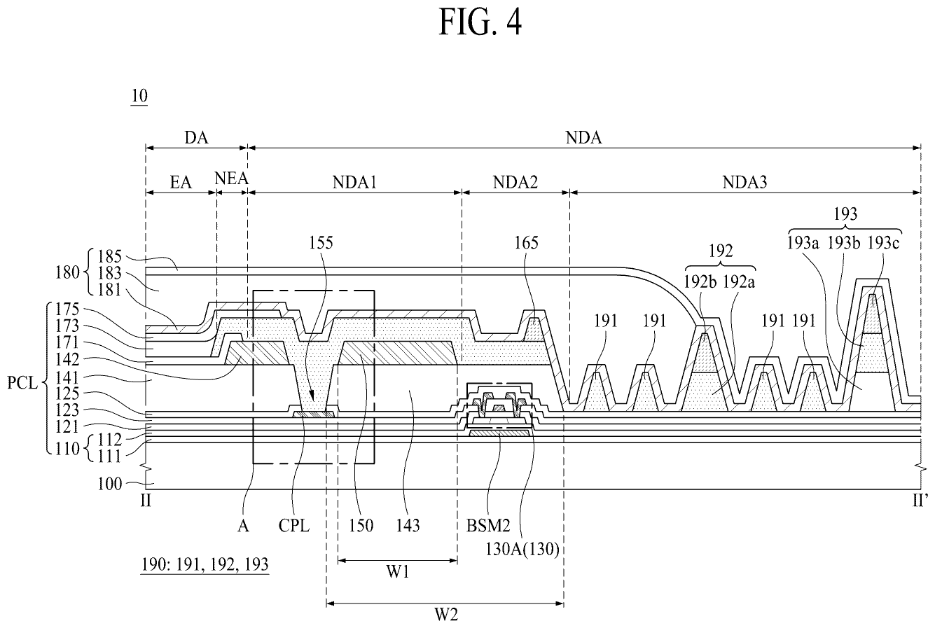

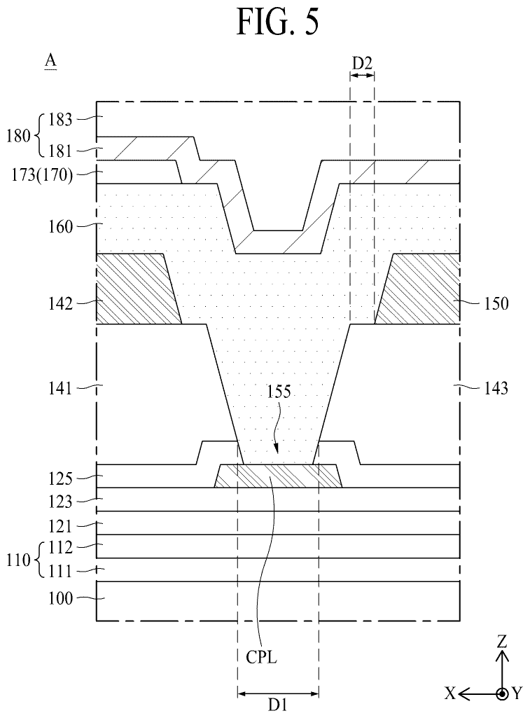

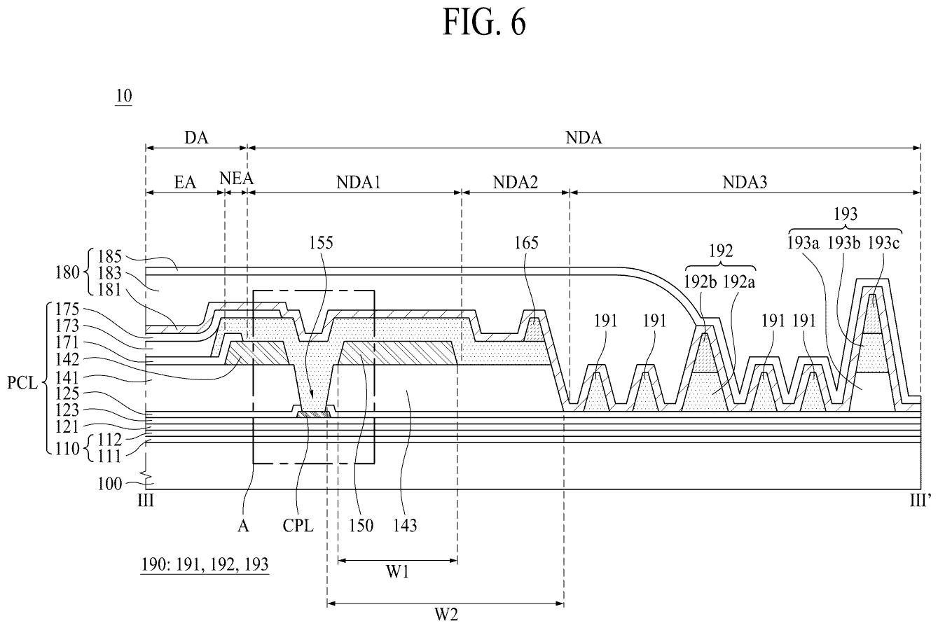

FIG. 4 is a cross-sectional view taken along line II-II′ of FIG. 1. FIG. 5 is an enlarged view illustrating portion ‘A’ illustrated in FIG. 4. FIG. 6 is a cross-sectional view taken along line III-III′ of FIG. 1. The enlarged view of the portion ‘A’ illustrated in FIG. 6 is a same as FIG. 5.

As shown in FIG. 1, and 4 to 6, a substrate 100 may include a display area DA and a non-display area NDA.

The non-display area NDA may include a first non-display area NDA1 extending from the display area DA, a second non-display area NDA2 extending from the first non-display area NDA1, and a third non-display area NDA3 extending from the second non-display area NDA2. The non-display area NDA may include the first non-display area NDA1 adjacent to the display area DA, the second non-display area NDA2 adjacent to the first non-display area NDA1, and the third non-display area NDA3 adjacent to the second non-display area NDA2.

A pixel circuit layer PCL may include a buffer layer 110, a black blocking layer BSM, a pixel circuit PC, first and second overcoat layers 141 and 142, and a light emitting device layer 170. Since the pixel circuit layer PCL has been described above with reference to FIGS. 1 to 3, hereinafter, therefore, a brief description will be given below or the description will be omitted.

The buffer layer 110 may be disposed on the substrate 100. The buffer layer 110 may be disposed at an entire surface of the display area DA and the non-display area NDA of the substrate 100. The buffer layer 110 may include a first buffer layer 111 and a second buffer layer 112.

The first buffer layer 111 may extend from the display area DA and may be disposed between the substrate 100 and a gate driving circuit 130. The first buffer layer 111 may serve to prevent or block a material of the substrate 100 from being diffused to a transistor in performing a high temperature process in a manufacturing process of the gate driving circuit 130.

The second buffer layer 112 may extend from the display area DA and may be disposed over the first buffer layer 111. The second buffer layer 112 may be disposed to cover a second blocking layer BSM2. The second buffer layer 112 may be disposed between the second blocking layer BSM2 and the gate driving circuit 130. For example, the second buffer layer 112 may be disposed between the second blocking layer BSM2 and an active layer of the gate driving circuit 130 (or a first gate driving circuit 130A).

The second blocking layer BSM2 may be disposed at the non-display area NDA. The second blocking layer BSM2 may be disposed under the gate driving circuit 130. The second blocking layer BSM2 may be configured to prevent or suppress changes in the threshold voltage Vth of thin film transistors in the gate driving circuit 130 caused by external light incident from outside the display panel.

The gate driving circuit 130 may be disposed at the non-display area NDA of the substrate 100. The gate driving circuit 130 may be disposed at the second non-display area NDA2 of the substrate 100. The gate driving circuit 130 may be connected to a gate line GL disposed at the display area DA of the substrate 100. The gate driving circuit 130 may have a same structure as a driving thin film transistor, but is not limited thereto. For example, the gate driving circuit 130 may include an active, a gate electrode, a source electrode, and a drain electrode.

According to an example embodiment of the present disclosure, the light emitting display apparatus 10 may further include a common power line CPL. The common power line CPL may be disposed at the first non-display area NDA1 of the substrate 100. The common power line CPL may be disposed at a same layer as a source electrode or a drain electrode disposed at the display area DA. The common power line CPL may include a same material as the source electrode or the drain electrode disposed at the display area DA, but is not limited thereto. A common power for driving a second electrode 175 may be applied to the common power line CPL.

A passivation layer 125 may be disposed at the display area DA and the non-display area NDA. The passivation layer 125 may be disposed over the gate driving circuit 130. The passivation layer 125 may be configured to cover the gate driving circuit 130.

According to an example embodiment of the present disclosure, the passivation layer 125 may be configured to cover one end and the other end of the common power line CPL. The passivation layer 125 may not be disposed at a center portion of the common power line CPL. The center portion of the common power line CPL may not overlap the passivation layer 125.

The first overcoat layer 141 may be disposed at the display area DA and the first non-display area NDA1. The first overcoat layer 141 may be disposed over the passivation layer 125 which is disposed at the display area DA and the first non-display area NDA1 of the substrate 100.

The second overcoat layer 142 may be disposed at the display area DA and the first non-display area NDA1. The second overcoat layer 142 may be disposed at the display area DA and the first non-display area NDA1 of the substrate 100.

A third overcoat layer 143 may be disposed at the non-display area NDA of the substrate 100. The third overcoat layer 143 may be disposed at the first non-display area NDA1 and the second non-display area NDA2. The third overcoat layer 143 may be disposed over the passivation layer 125 which is disposed in the first non-display area NDA1 and the second non-display area NDA2. The third overcoat layer 143 may be configured to cover the gate driving circuit 130.

The third overcoat layer 143 may be disposed around the first overcoat layer 141. The third overcoat layer 143 may be spaced apart from the first overcoat layer 141. As the third overcoat layer 143 is spaced apart from the first overcoat layer 141, a separation space (or a spacing space) may be configured (or formed) between the third overcoat layer 143 and the first overcoat layer 141. A separation distance D1 between the first overcoat layer 141 and the third overcoat layer 143 may be 20 μm or less. The separation distance D1 between the first overcoat layer 141 and the third overcoat layer 143 may be referred to as a first distance or a first separation distance (or a first spacing distance). For example, when the separation distance D1 between the first overcoat layer 141 and the third overcoat layer 143 exceeds 20 μm, an amount of bank material exceeding the volume (or capacity) for a trench part 155 may flow down (or overflow) in a subsequent bank forming process. In this case, the bank material may be insufficiently applied (or dispensed) to the side surfaces and upper surfaces of the first overcoat layer 141 and the second overcoat layer 142 adjacent to the third overcoat layer 143. When the bank material is insufficiently applied (or dispensed) to the side surfaces and upper surfaces of the second overcoat layer 142 due to the flow of the bank material, a thickness of the bank 160 covering the side surfaces and upper surfaces of the second overcoat layer 142 may become thin. To prevent or suppress this, the separation distance D1 between the first overcoat layer 141 and the third overcoat layer 143 may be set (or adjusted) to 20 μm or less.

According to an example embodiment of the present disclosure, as the first overcoat layer 141 and the third overcoat layer 143 are spaced apart from each other, the trench part 155 may be formed between the first overcoat layer 141 and the third overcoat layer 143. For example, as the first overcoat layer 141 and the third overcoat layer 143 are spaced apart from each other, a portion of the upper surface of the common power line CPL may not be covered by the overcoat layers 141 and 143.

For example, when the first overcoat layer 141 and the third overcoat layer 143 are not spaced apart and are connected to form one layer (or a single layer), a moisture may penetrate into the display panel through the overcoat layers 141 and 143 in an outer area or the non-display area NDA of the light emitting display apparatus 10. For example, when the first overcoat layer 141 and the third overcoat layer 143 are connected to form one layer (or a single layer), the overcoat layers 141 and 143 may be a moisture permeation path.

According to an example embodiment of the present disclosure, as the first overcoat layer 141 and the third overcoat layer 143 are spaced apart from each other, hydrogen and moisture from the outer area or the non-display area NDA of the light emitting display apparatus 10 may be prevented or suppressed from penetrating into the display area DA. According to an example embodiment of the present disclosure, as the first overcoat layer 141 and the third overcoat layer 143 are spaced apart from each other, hydrogen and moisture penetrating from the outer area or the non-display area NDA may not reach the first overcoat layer 141 and may be blocked by the trench part 155. Accordingly, the moisture permeation path from the outer area or the non-display area NDA of the light emitting display apparatus 10 may be blocked, deterioration of the light emitting display apparatus 10 may be prevented or suppressed, and reliability of the light emitting display apparatus 10 may be improved.

According to an example embodiment of the present disclosure, the third overcoat layer 143 may be disposed at a same layer as the first overcoat layer 141. The third overcoat layer 143 may include at same material as the first overcoat layer 141 and may be configured (or formed) using a same process. Accordingly, the light emitting display apparatus 10 according to an example embodiment of the present disclosure may protect the gate driving circuit 130 and easily block the moisture permeation path of the light emitting display apparatus 10 without adding a process.

The light emitting display apparatus 10 according to an example embodiment of the present disclosure may include a step compensation layer 150.

The step compensation layer 150 may be disposed at the non-display area NDA of the substrate 100. The step compensation layer 150 may be disposed at the first non-display area NDA1 of the substrate 100. The step compensation layer 150 may be disposed over the third overcoat layer 143. The step compensation layer 150 may be configured to include an inclined surface (or a structure) where an upper surface is flat and a side surface is inclined. The step compensation layer 150 may have a width smaller than the width of the third overcoat layer 143. A width W1 of the step compensation layer 150 may be smaller than a width W2 of the third overcoat layer 143. For example, the width W1 of the step compensation layer 150 may be 50% or more and less than 100% of the width W2 of the third overcoat layer 143, but is not limited thereto. Accordingly, the step compensation layer 150 may be easily settled over the third overcoat layer 143. Accordingly, the step compensation layer 150 may compensate a step difference between the first and second overcoat layers 141, 142 and the third overcoat layer 143 in a subsequent process of forming the bank 160.

According to an example embodiment of the present disclosure, one side end of the third overcoat layer 143 may protrude toward a direction of the display area DA than one side end of the step compensation layer 150. Accordingly, a lower surface of the step compensation layer 150 and an upper surface of the third overcoat layer 143 may be in contact with each other, and the lower surface of the step compensation layer 150 and the upper surface of the third overcoat layer 143 which are in contact with each other may be spaced apart from each other in at least one of the first direction X and the second direction Y. For example, a separation distance D2 between the lower surface of the step compensation layer 150 and the upper surface of the third overcoat layer 143 which are in contact with each other may be in a range of 3 μm to 10 μm. For example, the separation distance D2 between the lower surface of the step compensation layer 150 and the upper surface of the third overcoat layer 143 which are in contact with each other may be a second distance or a second separation distance (or a second spacing distance).

Accordingly, in a subsequent process of forming the bank 160, the bank material may be uniformly applied (or dispensed). For example, when the separation distance D2 between the lower surface of the step compensation layer 150 and the upper surface of the third overcoat layer 143 which are in contact with each other is less than 3 μm or more than 10 μm, the bank material may flow down (or overflow) to the trench part 155 and the outer area of the substrate 100 due to the step difference between the first and second overcoat layers 141, 142 and the trench part 155. In this case, a thickness of the bank 160 disposed at the side surface of the second overcoat layer 142 may become thin. Accordingly, in pixels which is disposed at the emission region adjacent to the non-display area NDA of the light emitting display apparatus 10, light emission defects may be occurred, and a viewing angle and luminance may be reduced. Therefore, the separation distance D2 between the lower surface of the step compensation layer 150 and the upper surface of the third overcoat layer 143 which are in contact with each other may be set (or adjusted) to a range of 3 μm to 10 μm.

According to an example embodiment of the present disclosure, the light emitting display apparatus 10 include the step compensation layer 150, and thus, in the bank forming process, a bank material may be prevented or suppressed from flowing down (or overflowing) toward the trench part 155 and an outer region direction due to the step difference of the first and second overcoat layers 141 and 142.

The light emitting display apparatus 10 according to an example embodiment of the present disclosure may include the trench part 155. The trench part 155 may be disposed at the non-display area NDA of the substrate 100. The trench part 155 may be disposed at the first non-display area NDA1 of the substrate 100. The trench part 155 may be a region where the passivation layer 125 is not configured in the first non-display area NDA1. The trench part 155 may be a region between the first overcoat layer 141 and the third overcoat layer 143 in the first non-display area NDA1. The trench part 155 may overlap the common power line CPL. The trench part 155 may overlap a center region of an upper surface of the common power line CPL. The trench part 155 may be disposed between the display area DA and the gate driving circuit 130 of the substrate 100.

According to an example embodiment of the present disclosure, the light emitting display apparatus 10 include the trench part 155, and thus, the moisture permeation path from the outer area or the non-display area NDA of the light emitting display apparatus 10 may be blocked, accordingly, the moisture permeation path from the outer area or the non-display area NDA of the light emitting display apparatus 10 may be blocked, deterioration of the light emitting display apparatus 10 may be prevented or suppressed, and reliability of the light emitting display apparatus 10 may be improved.

The light emitting display apparatus 10 according to an example embodiment of the present disclosure may include a bank 160. The bank 160 may cover an edge portion of the first electrode 171 and may be extended from the display area DA to the non-display area NDA. The bank 160 may be configured to cover the second overcoat layer 142, the trench part 155, the third overcoat layer 143 and the step compensation layer 150. The bank 160 may be configured to cover the common power line CPL. For example, the bank 160 may be formed of an organic material and may be a transparent bank, a semi-transparent bank, or a black bank.

According to an example embodiment of the present disclosure, a material forming (or configuring) the bank 160 may be applied (or dispensed) from the display area DA to the non-display area NDA of the substrate 100 and may be patterned at the display area DA, the first non-display area NDA1, and the second non-display area NDA2. For example, the material forming (or configuring) the bank 160 may be configured as an organic material having fluidity. For example, in a process of applying (or dispensing) the bank material to the second overcoat layer 142, the trench part 155, and the second non-display area NDA2, when the light emitting display apparatus 10 includes only the trench part 155 and does not include the step compensation layer 150, the organic material may flow down (or overflow) toward a direction of the trench part 155 and the second non-display area NDA2 due to the step difference of the second overcoat layer 142, the trench part 155 and the second non-display area NDA2. In this case, the thickness of the bank 160 at the side surface of the second overcoat layer 142 adjacent to the trench part 155 may become thin. Accordingly, in an outermost emission region EA of the light emitting display apparatus 10, a light emission abnormality (or abnormal light emission) may be occurred. Therefore, in the outermost emission region EA of the light emitting display apparatus 10, luminance may be decreased (or reduced) based on a viewing angle.

According to an example embodiment of the present disclosure, the light emitting display apparatus 10 includes the step compensation layer 150, so that the step difference between the first and second overcoat layers 141, 142 and the trench part 155 and the third overcoat layer 143 may be compensated. Accordingly, in the light emitting display apparatus 10 according to an example embodiment of the present disclosure, even when the trench part 155 is configured at the non-display area DNA to block the moisture permeation path, the thickness of the bank 160 may be prevented or suppressed from being reduced due to the collapse of the bank 160 which is formed (or disposed) subsequently. According to an example embodiment of the present disclosure, the light emitting display apparatus 10 includes the step compensation layer 150, so that the bank material may be prevented or suppressed from collapsing or flowing down (or overflowing) to the first non-display area NDA1 and the second non-display area NDA2 in a subsequent process of forming the bank 160. Accordingly, the bank 160 may be configured (or formed) to have a uniform thickness at the upper surface and the side surface of the second overcoat layer 142 disposed at the outermost emission region EA of the light emitting display apparatus 10.

Therefore, the moisture permeation path from the outside of the light emitting display apparatus 10 may be blocked, and the light emission abnormality (or abnormal light emission) in the outermost emission region EA of the light emitting display apparatus 10 may be prevented or suppressed. Thus, luminance decrease (or luminance reduction) according to the viewing angle in the outermost emission region EA of the light emitting display apparatus 10 may be prevented or suppressed.

The light emitting display apparatus 10 according to an example embodiment of the present disclosure may further include a spacer 165.

The spacer 165 may be disposed at the second non-display area NDA2. The spacer 165 may be disposed over the bank 160. The spacer 165 may be disposed at a portion of an upper portion of the bank 160. The spacer 165 may be disposed at a region where the light emitting device layer 170 is not disposed. In the second non-display area NDA2, the light emitting device 173 and the second electrode 175 may be spaced apart from the spacer 165. In the second non-display area NDA2, the light emitting device 173 and the second electrode 175 may not be configured on the upper portion of the spacer 165. The spacer 165 may be configured to prevent a screen mask and the substrate 100 (or the bank 160) during the deposition process of the light emitting device 173.

The gate driving circuit 130 may be disposed at the non-display area NDA of the substrate 100. The gate driving circuit 130 may be disposed at the second non-display area NDA2 of the substrate 100. As illustrated in FIG. 1, the gate driving circuit 130 may be connected to the gate line GL configured at the display area DA. The gate driving circuit 130 may be formed as an integrated circuit at the second non-display area NDA2 of the substrate 100 together with the manufacturing process of the pixel circuit PC, that is, the manufacturing process of the thin film transistor.

The gate driving circuit 130 generate a scan signal based on a gate control signal supplied from the panel driving circuit part 300 illustrated in FIG. 1 and output the generated scan signal in a predetermined order, and thus, may drive each of the plurality of gate lines GL in a predetermined order.

The light emitting display apparatus 10 according to an example embodiment of the present disclosure may further include a dam part 190.

The dam part 190 may be disposed at the non-display area NDA of the substrate 100. The dam part 190 may be disposed at the third non-display area NDA3 of the substrate 100. The dam part 190 may be disposed an outer side of the common power line CPL. The dam part 190 may be located at an outermost portion of the substrate 100. The dam part 190 may be disposed to surround the display area DA. The dam part 190 may be configured to prevent or suppress the organic material configuring (or forming) the encapsulation part 180 from overflowing to an outer portion (or an outer area) of the substrate 100.

According to an example embodiment of the present disclosure, the dam part 190 may include a first to third dam 191, 192, and 193.

A plurality of first dams 191 may be provided. Each of the plurality of first dams 191 may be disposed between the common power line CPL and the second dam 192, and between the second dam 192 and the third dam 193. Each of the plurality of first dams 191 may be configured as a single layer. Each of the plurality of first dams 191 may be formed through a same process as the bank 160 and may include a same organic material.

The second dam 192 may be disposed between the first dam 191 and the third dam 193. The second dam 192 may have a stacked structure. For example, the second dam 192 may include a sequentially stacked a 2-1^{th} dam 192a and a 2-2^{th} dam 192b. For example, the 2-1^{th} dam 192a may be formed through the same process as the bank 160 and may include the same organic material. For example, the 2-2^{th} dam 192b may be formed through a same process as the spacer 165 and may include a same organic material.

According to an example embodiment of the present disclosure, the second dam 192 may be thicker than the first dam 191. For example, a distance from the substrate 100 to the second dam 192 may be greater than a distance from the substrate 100 to the first dam 191. Accordingly, the second encapsulation part 183 (or the organic material layer) formed subsequently may be configured to cover the common power line CPL and the first dam 191 between the common power line CPL and the second dam 192. For example, the second encapsulation part 183 (or organic material layer) formed subsequently may be disposed at one side surface of the second dam 192 and may not be disposed at an upper surface of the second dam 192. For example, the second encapsulation part 183 (or organic material layer) may not overlap an upper surface of the second dam 192, the first dam 191 which is disposed between the second dam 192 and the third dam 193, and the third dam 193.

Accordingly, the light emitting display apparatus 10 according to an example embodiment of the present disclosure may include the second dam 192, and thus, the second encapsulation part 183 (or the organic material layer) may be prevented or suppressed from overflowing to the outermost portion of the substrate 100.

The third dam 193 may be disposed at the outermost portion of the substrate 100. Some of the plurality of first dams 191 may be disposed between the second dam 192 and the third dam 193, and the third dam 193 may surround the some of the plurality of first dams 191. For example, the third dam 193 may have a stacked structure. For example, the third dam 193 may include sequentially stacked 3-1^{th} dam to 3-3^{th} dam 193a, 193b, and 193c. For example, the 3-1^{th} dam 193a may be formed through a same process as the first overcoat layer 141 and may include a same organic material. For example, the 3-2^{th} dam part 193b may be formed through the same process as a bank 160 and may include a same organic material. For example, the 3-3^{th} dam 193c may be formed through a same process as a spacer 165 and may include a same organic material.

According to an example embodiment of the present disclosure, the light emitting display apparatus 10 may include the third dam 193, and thus, the second encapsulation part 183 (or organic material layer) may be further prevented or suppressed from overflowing to the outermost portion of the substrate 100.

The first to third dams 191, 192, and 193 may have different thicknesses or different heights. For example, a distance from the substrate 100 to the upper surface of each of the first to third dams 191, 192, and 193 may be different from one another. The first to third dams 191, 192, and 193 may be spaced apart by a predetermined distance.

According to an example embodiment of the present disclosure, the light emitting display apparatus 10 may include the first to third dams 191, 192, and 193, and thus, when a crack occurs in the first encapsulation part 181, the third encapsulation part 185, or an inorganic material layer configuring the encapsulation part 180, the crack may be prevented or suppressed from propagating toward the display panel. Accordingly, penetration of hydrogen and moisture into the light emitting display apparatus 10 may be further prevented or suppressed.

The encapsulation part (or an encapsulation layer) 180 may be configured to cover or surround the pixel circuit layer PCL described above with reference to FIG. 3. For example, the encapsulation part 180 may be disposed over the light emitting device layer 170 and cover or surround the light emitting device layer 170. The encapsulation part 180 may be configured to protect the pixel circuit layer PCL. For example, the encapsulation part 180 may be configured to prevent or block oxygen or moisture from the outside from penetrating into the emission structure of the pixel circuit layer PCL.

The encapsulation part 180 may include one or more encapsulation parts. For example, the encapsulation part 180 may include one or more inorganic material layers and one or more organic material layers on the light emitting device layer 170. For example, the encapsulation part 180 may include the first encapsulation part 181, the second encapsulation part 183, and the third encapsulation part 185.

The first encapsulation part 181 may be disposed at the display area DA and the non-display area NDA to cover the light emitting device layer 170. The first encapsulation part 181 may be disposed to cover the second electrode 175. The first encapsulation part 181 may extend from the display area DA and may be disposed at the display area DA and the non-display area NDA to cover the spacer 165, the bank 160, the first overcoat layer 141, the second overcoat layer 142, the third overcoat layer 143, the step compensation layer 150, the common power line CPL, and the dam part 190. For example, the first encapsulation part 181 may be an inorganic material layer.

The second encapsulation part 183 may be disposed at the first encapsulation part 181. The second encapsulation part 183 may extend from the display area DA to one side surface of the second dam 192 in the non-display area NDA. The second encapsulation part 183 may extend from the display area DA to the one side surface of the second dam 192 and may not be configured (or disposed) on the upper surface of the second dam 192. For example, the second encapsulation part 183 may be an organic material layer.

The third encapsulation part 185 may be disposed on the first encapsulation part 181 and the second encapsulation part 183. The third encapsulation part 185 may be disposed on the first encapsulation part 181 and the second encapsulation part 183 which are configured (or disposed) at the display area DA. The third encapsulation part 185 may be disposed on the first encapsulation part 181 and the second encapsulation part 183 which are configured (or disposed) at the non-display area NDA. For example, the third encapsulation part 185 may be an inorganic material layer.

The first encapsulation part 181 and the third encapsulation part 185 may be connected to (or in contact with) each other at the upper surface of the second dam 192. The first encapsulation part 181 and the third encapsulation part 185 may be configured to cover the second dam 192, the first dam 191 between the second dam 192 and the third dam 193, and the third dam 193. The first encapsulation part 181 and the third encapsulation part 185 may be connected to (or in contact with) each other at an upper portion of the second dam 192, the first dam 191 between the second dam 192 and the third dam 193, and the third dam 193.

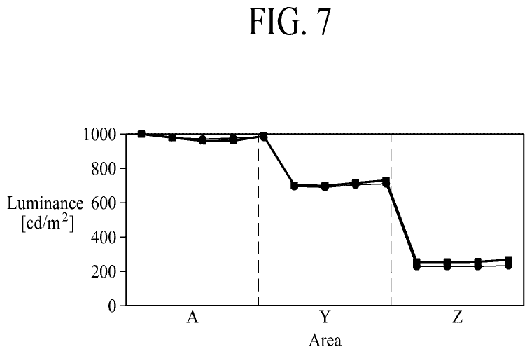

FIG. 7 illustrates luminance according to a viewing angle of a light emitting display apparatus according to an example embodiment of the present disclosure.

To compare luminance based on ae viewing angle of the light emitting display apparatus according to an example embodiment of the present disclosure, the inventors of the present disclosure prepared samples as an experimental example and an example embodiment. In the experimental example, a light emitting display apparatus in which only a trench part is configured at the light emitting display apparatus described above with reference to FIGS. 1 to 6 and a step compensation layer is not configured was prepared. In an example embodiment of the present disclosure, as described with reference to FIGS. 1 to 6, a light emitting display apparatus including the trench part and the step compensation layer was prepared. In FIG. 7, a solid line represents the luminance based on the experimental example, and a thick solid line represents the luminance based on the example embodiment. In FIG. 7, the luminance of the prepared samples was measured in each of an A viewing angle region, a Y viewing angle region, and a Z viewing angle region. For example, a vertical portion (or front portion) with respect to a front center of the display apparatus is the A viewing angle region, a side portion with respect to the front center of the display apparatus is the Z viewing angle region, and the Y viewing angle region may be a region between the A viewing angle region and the Z viewing angle region. For example, from the A viewing angle region toward (or progressively toward) the Y viewing angle region and the Z viewing angle region, an angle of the viewing angle may change from a low angle to a high angle. For example, the low angle may be a vertical region with respect to the front center of the display apparatus, and the high angle may be a side region with respect to the front center of the display apparatus.

As shown in FIG. 7, in the A viewing angle region and the Y viewing angle region, the luminance of each of the light emitting display apparatus according to the experimental example and the example embodiment was similarly measured. In the Z viewing angle region, the luminance of the light emitting display apparatus according to the example embodiment was confirmed to be improved by about 10% compared to that of the light emitting display apparatus according to the experimental example.

Accordingly, the light emitting display apparatus according to an example embodiment of the present disclosure includes the trench part and the step compensation layer, whereby a reduction in a thickness of a bank in an outermost emission region of the light emitting display apparatus may be prevented or suppressed, and thus, it was confirmed that the luminance is improved in the Z viewing angle region.

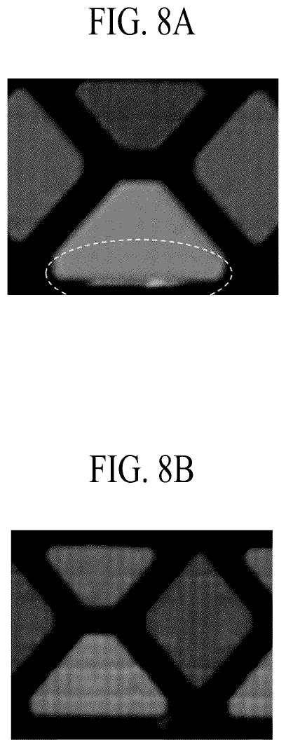

FIG. 8A is a diagram illustrating a pixel of a light emitting display apparatus according to an experimental example, and FIG. 8B is a diagram illustrating a pixel of a light emitting display apparatus according to an example embodiment of the present disclosure.

To check (or confirm) light emission defects (or light emission failures) of the light emitting display apparatus according to an example embodiment of the present disclosure, the inventors of the present disclosure prepared samples as an experimental example and an example embodiment. The samples for each of the experimental example and the example embodiment were prepared in the same manner as in FIG. 7.

As shown in FIG. 8A, in the case of the light emitting display apparatus of the experimental example or including only the trench part, it was confirmed that light emission defects occurred in an outermost emission region of the light emitting display apparatus. A region in which the light emission defects occurred is indicated by a dotted line in FIG. 8A.

As shown in FIG. 8B, in the case of the light emitting display apparatus according to the example embodiment of the present disclosure or including the trench part and the step compensation layer, it was confirmed that the light emission defects did not occur in an outermost emission region of the light emitting display apparatus.

Accordingly, the light emitting display apparatus according to an example embodiment of the present disclosure includes the trench part and the step compensation layer, whereby a reduction in a thickness of a bank in an outermost emission region of the light emitting display apparatus may be prevented or suppressed, and thus, it was confirmed that the light emission defects did not occur in the outermost emission region of the light emitting display apparatus.

The light emitting display apparatus according to one or more example embodiments of the present disclosure may be described as follows.

According to an example embodiment of the present disclosure, the light emitting display apparatus may comprise a substrate including a display area and a non-display area; a pixel circuit layer including a gate line and a data line configured at the display area, and a pixel circuit connected to the gate line and the data line; a first overcoat layer configured to cover the pixel circuit layer; a second overcoat layer over the first overcoat layer; a light emitting device layer over the first overcoat layer and the second overcoat layer and configured to connect to the pixel circuit; a gate driving circuit configured at the non-display area and connected to the gate line; a third overcoat layer in a same layer as the first overcoat layer and configured to cover the gate driving circuit; a step compensation layer over the third overcoat layer; and a trench part between the first overcoat layer and the third overcoat layer.

According to an example embodiment of the present disclosure, the third overcoat layer and the step compensation layer may be disposed at the non-display area.

According to an example embodiment of the present disclosure, the third overcoat layer may be spaced apart from the first overcoat layer and be disposed around the first overcoat layer.

According to an example embodiment of the present disclosure, the step compensation layer may be spaced apart from the second overcoat layer and be disposed around the second overcoat layer.

According to an example embodiment of the present disclosure, the non-display area may include a first non-display area adjacent to the display area, and a second non-display area adjacent to the first non-display area. The trench part and the step compensation layer may be at the first non-display area.

According to an example embodiment of the present disclosure, the gate driving circuit may be at the second non-display area.

According to an example embodiment of the present disclosure, the light emitting display apparatus may further comprise a bank configured to cover the second overcoat layer, the trench part, the third overcoat layer, and the step compensation layer.

According to an example embodiment of the present disclosure, the light emitting device layer may comprise a first electrode over the first overcoat layer, a light emitting layer over the first electrode, and a second electrode over the light emitting layer. The first electrode may be configured to cover an upper surface of the first overcoat layer and a side surface of the second overcoat layer adjacent to the upper surface of the first overcoat layer.

According to an example embodiment of the present disclosure, the light emitting display apparatus may further comprise a bank configured to cover an edge portion of the first electrode and extending to the non-display area.

According to an example embodiment of the present disclosure, the bank may be configured to cover the second overcoat layer, the trench part, the third overcoat layer, and the step compensation layer.

According to an example embodiment of the present disclosure, the light emitting display apparatus may further comprise a common power line disposed at the non-display area and configured at a same layer as the data line. The bank may be configured to cover the common power line.

According to an example embodiment of the present disclosure, the light emitting display apparatus may further comprise a common power line disposed at the non-display area and configured at a same layer as the data line. The trench part may be configured to overlap the common power line.

According to an example embodiment of the present disclosure, a distance between the first overcoat layer and the third overcoat layer may be 20 μm or less.

According to an example embodiment of the present disclosure, a width of the step compensation layer may be smaller than a width of the third overcoat layer.

According to an example embodiment of the present disclosure, a separation distance between a lower surface of the step compensation layer and an upper surface of the third overcoat layer may be in a range from 3 μm to 10 μm.

According to an example embodiment of the present disclosure, the substrate may comprise a first long-side, a second long-side parallel to the first long-side, a first short-side, and a second short-side parallel to the first short-side. The gate driving circuit may be configured at the non-display area adjacent to the first short-side of the substrate.

According to an example embodiment of the present disclosure, the trench part may be between the display area of the substrate and the gate driving circuit.

According to an example embodiment of the present disclosure, the light emitting display apparatus may further comprise an encapsulation part configured to cover the light emitting device layer and the bank. The encapsulation part may comprise a first encapsulation part disposed at the display area and the non-display area to cover the light emitting device layer and the bank, a second encapsulation part disposed on the first encapsulation part, and a third encapsulation part disposed on the first encapsulation part and the second encapsulation part.

According to an example embodiment of the present disclosure, the non-display area may comprise a first non-display area adjacent to the display area, a second non-display area adjacent to the first non-display area, and a third non-display area adjacent to the second non-display area. The third non-display area may comprise a dam part configured on the substrate.

According to an example embodiment of the present disclosure, the dam part may comprise a plurality of first dams, a second dam between the plurality of first dams, and a third dam spaced apart from the second dam with at least one of the plurality of first dams therebetween. The first encapsulation part and the third encapsulation part may be in contact with each other at an upper surface of the second dam.

According to an example embodiment of the present disclosure, some of the plurality of first dams 191 may be disposed between the second dam 192 and the third dam 193, and the third dam 193 may surround the some of the plurality of first dams 191.

The light emitting display apparatus according to an example embodiment of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like.

It will be apparent to those skilled in the art that various modifications and variations can be made in the present disclosure without departing from the spirit or scope of the disclosures. Thus, it is intended that the present disclosure covers the modifications and variations of this disclosure provided that within the scope of the claims and their equivalents.

What is claimed is:

1. A light emitting display apparatus, comprising:
a substrate including a display area and a non-display area;
a pixel circuit layer including a gate line and a data line configured at the display area, and a pixel circuit connected to the gate line and the data line;
a first overcoat layer configured to cover the pixel circuit layer;
a second overcoat layer over the first overcoat layer;
a light emitting device layer over the first overcoat layer and the second overcoat layer and configured to connect to the pixel circuit;
a gate driving circuit configured at the non-display area and connected to the gate line;
a third overcoat layer in a same layer as the first overcoat layer and configured to cover the gate driving circuit;
a step compensation layer over the third overcoat layer; and
a trench part between the first overcoat layer and the third overcoat layer.

2. The light emitting display apparatus of claim 1, wherein the third overcoat layer and the step compensation layer are disposed at the non-display area.

3. The light emitting display apparatus of claim 1, wherein the third overcoat layer is spaced apart from the first overcoat layer and is disposed around the first overcoat layer.

4. The light emitting display apparatus of claim 1, wherein the step compensation layer is spaced apart from the second overcoat layer and is disposed around the second overcoat layer.

5. The light emitting display apparatus of claim 1, wherein:
the non-display area includes:
a first non-display area adjacent to the display area; and
a second non-display area adjacent to the first non-display area; and
the trench part and the step compensation layer are at the first non-display area.

6. The light emitting display apparatus of claim 5, wherein the gate driving circuit is at the second non-display area.

7. The light emitting display apparatus of claim 1, further comprising a bank configured to cover the second overcoat layer, the trench part, the third overcoat layer, and the step compensation layer.

8. The light emitting display apparatus of claim 1, wherein:
the light emitting device layer comprises:
a first electrode over the first overcoat layer;
a light emitting layer over the first electrode; and
a second electrode over the light emitting layer; and
the first electrode is configured to cover an upper surface of the first overcoat layer and a side surface of the second overcoat layer adjacent to the upper surface of the first overcoat layer.

9. The light emitting display apparatus of claim 8, further comprising a bank configured to cover an edge portion of the first electrode and extending to the non-display area.

10. The light emitting display apparatus of claim 9, wherein the bank is configured to cover the second overcoat layer, the trench part, the third overcoat layer, and the step compensation layer.

11. The light emitting display apparatus of claim 7, further comprising a common power line disposed at the non-display area and configured at a same layer as the data line,
wherein the bank is configured to cover the common power line.

12. The light emitting display apparatus of claim 1, further comprising a common power line disposed at the non-display area and configured at a same layer as the data line,
wherein the trench part is configured to overlap the common power line.

13. The light emitting display apparatus of claim 1, wherein a distance between the first overcoat layer and the third overcoat layer is 20 μm or less.

14. The light emitting display apparatus of claim 1, wherein a width of the step compensation layer is smaller than a width of the third overcoat layer.

15. The light emitting display apparatus of claim 1, wherein a separation distance between a lower surface of the step compensation layer and an upper surface of the third overcoat layer is in a range from 3 μm to 10 μm.

16. The light emitting display apparatus of claim 1, wherein:
the substrate comprises a first long-side, a second long-side parallel to the first long-side, a first short-side, and a second short-side parallel to the first short-side; and
the gate driving circuit is configured at the non-display area adjacent to the first short-side of the substrate.

17. The light emitting display apparatus of claim 1, wherein the trench part is between the display area of the substrate and the gate driving circuit.

18. The light emitting display apparatus of claim 7, further comprising an encapsulation part configured to cover the light emitting device layer and the bank,
wherein the encapsulation part comprises:
a first encapsulation part disposed at the display area and the non-display area to cover the light emitting device layer and the bank;
a second encapsulation part disposed on the first encapsulation part; and
a third encapsulation part disposed on the first encapsulation part and the second encapsulation part.

19. The light emitting display apparatus of claim 18, wherein:
the non-display area comprises:
a first non-display area adjacent to the display area;
a second non-display area adjacent to the first non-display area; and
a third non-display area adjacent to the second non-display area; and
the third non-display area comprises a dam part configured on the substrate.

20. The light emitting display apparatus of claim 19, wherein:
the dam part comprises:
a plurality of first dams;
a second dam between the plurality of first dams; and
a third dam spaced apart from the second dam with at least one of the plurality of first dams therebetween; and
the first encapsulation part and the third encapsulation part are in contact with each other at an upper surface of the second dam.
